(19) United States
(12) Patent Application Publication
(10) Pub. No.: US 2025/0218623 A1
(43) Pub. Date: Jul. 3, 2025

(54) DATA TRANSMISSION CABLE AND DISPLAY APPARATUS INCLUDING THE SAME

(71) Applicant: LG ELECTRONICS INC., Seoul (KR)

(72) Inventor: Joongeol CHA, Seoul (KR)

(73) Assignee: LG ELECTRONICS INC., Seoul (KR)

(21) Appl. No.: 18/791,872

(22) Filed: Aug. 1, 2024

(30) Foreign Application Priority Data
Jan. 2, 2024 (KR) 10-2024-0000561

(51) Int. Cl. H01B 11/06; H01B 7/04; H01B 7/08; H03H 7/38

(52) U.S. Cl. CPC H01B 11/06; H01B 7/04; H03H 7/38; H01B 7/0861

(57) ABSTRACT

The present disclosure relates to a data transmission cable that may reduce electromagnetic interference (EMI) noise generated during data transmission and a display apparatus including the same and may include a signal transfer line; an impedance matching sheet configured to cover the signal transfer line; and, a conductive bending tape wound around the impedance matching sheet, in which the conductive bending tape may be disposed to be wound on an outer surface of the impedance matching sheet in a direction perpendicular to a longitudinal direction of the impedance matching sheet.

### CROSS-REFERENCE TO RELATED APPLICATION(S)

Pursuant to 35 U.S.C. § 119(a), this application claims the benefit of earlier filing date and right of priority to Korean Patent Application No. 10-2024-0000561, filed on Jan. 2, 2024, the contents of which are all incorporated by reference herein in its entirety.

### FIELD

The present disclosure relates to a data transmission cable that may reduce electromagnetic interference (EMI) noise generated during data transmission and a display apparatus including the same.

### BACKGROUND

In general, digital electronic devices transmit all data as electrical signals, and in particular, in the case of high-performance digital electronic devices, there is a need for a system that can effectively transmit large amounts of data between various components or devices without information loss.

In this way, since the signal transfer performance of digital electronic devices is directly related to the performance of the product, efforts are being made to improve the performance of the data transmission system, and in order to improve the performance of these digital electronic devices, there is a demand for interface technology that can realize faster signal transfer speeds due to the increase in data transmission volume.

A digital electronic device including a display apparatus is a transmission medium for data transmission and often uses flexible flat cables (FFC), which have low manufacturing costs while having physical flexibility and signal transfer characteristics equivalent to those of flexible printed circuits (FPC).

However, these flexible flat cables have a problem in that, when transmitting large amounts of data at high speeds, noise is easily generated due to the high frequency of the data signal, resulting in Electro Magnetic Interference (EMI) noise that can cause data loss and malfunction.

Therefore, in the future, there is a need to develop a data transmission cable that can reduce EMI noise generation at minimal cost.

### SUMMARY

An object of the present disclosure is to solve the above-described problems and other problems.

An object of the present disclosure is to provide a data transmission cable capable of reducing EMI noise generation due to data transmission by wrapping a conductive bending tape on the outer surface of an impedance matching sheet, and a display including the same.

A data transmission cable according to an embodiment of the present disclosure may include a signal transfer line; an impedance matching sheet configured to cover the signal transfer line; and, a conductive bending tape wound around the impedance matching sheet, in which the conductive bending tape may be disposed to be wound on an outer surface of the impedance matching sheet in a direction perpendicular to a longitudinal direction of the impedance matching sheet.

A display apparatus including a data transmission cable according to an embodiment of the present disclosure may include a display unit configured to display an image; a driving control unit configured to control driving of the display unit; and, a data transmission cable connected between a first circuit part and a second circuit part of the driving control unit to transfer a data signal, in which the data transmission cable may include an impedance matching sheet configured to cover the signal transfer line, and a conductive bending tape wound on an outer surface of the impedance matching sheet in a direction perpendicular to a longitudinal direction of the impedance matching sheet.

According to one embodiment of the present disclosure, the data transmission cable can reduce the generation of EMI noise due to data transmission by disposing a conductive bending tape wound on the outer surface of the impedance matching sheet.

In addition, the present disclosure has a structure of wrapping a conductive bending tape on the outer surface of the impedance matching sheet in a direction perpendicular to the longitudinal direction of the impedance matching sheet, so the manufacturing cost may be low, an automated process may be possible, and EMI noise emission may be suppressed.

### BRIEF DESCRIPTION OF THE DRAWINGS

FIG. 1 is a view illustrating the overall configuration of a data transmission cable according to an embodiment of the present disclosure.

FIG. 2 is a view illustrating area A of FIG. 1 in detail.

FIG. 3 is a view illustrating the inside of a side of a data transmission cable in detail according to an embodiment of the present disclosure.

FIGS. 4 and 5 are views for explaining the structure of an impedance matching sheet according to an embodiment of the present disclosure.

FIGS. 6 and 7 are views for explaining the disposition position and the disposition number of conductive bending tapes according to an embodiment of the present disclosure.

FIGS. 8A and 8B are views for explaining the length of a conductive bending tape according to an embodiment of the present disclosure.

FIG. 9 is a diagram illustrating a lookup table in which a specific wavelength at which an impedance matching sheet operates as a noise antenna according to an embodiment of the present disclosure is preset.

FIGS. 10 and 11 are views for explaining a display apparatus including a data transmission cable according to an embodiment of the present disclosure.

FIGS. 12A and 12B are graphs illustrating noise reduction in a data transmission cable according to an embodiment of the present disclosure.

### DETAILED DESCRIPTION OF THE EMBODIMENTS

Hereinafter, embodiments disclosed in the present specification will be described in detail with reference to the attached drawings, wherein identical or similar components will be assigned the same reference numbers regardless of reference numerals, and duplicate descriptions thereof will be omitted. The suffixes ‘module’ and ‘part’ for components used in the following description are given or used interchangeably only considering the ease of writing the specification, and do not have distinct meanings or roles in themselves. Additionally, in describing the embodiments disclosed in this specification, when it is determined that detailed descriptions of related known technologies may obscure the subject matter of the embodiments disclosed in this specification, the detailed descriptions thereof will be omitted. In addition, it should be understood that the attached drawings are only for easy understanding of the embodiments disclosed in this specification, and the technical idea disclosed in this specification is not limited by the attached drawings, and all changes, equivalents, or substitutes included in the spirit and technical scope of the present disclosure are included.

Terms containing ordinal numbers, such as first and second may be used to describe various components, but the components are not limited by the terms. Terms are used only to distinguish one component from another.

When a component is said to be ‘connected’ or ‘joined’ to another component, it should be understood that it may be directly connected or joined to the other component, but that other components may exist in between. On the other hand, when a component is mentioned as being ‘directly connected’ or ‘directly joined’ to another component, it should be understood that there are no other components in between.

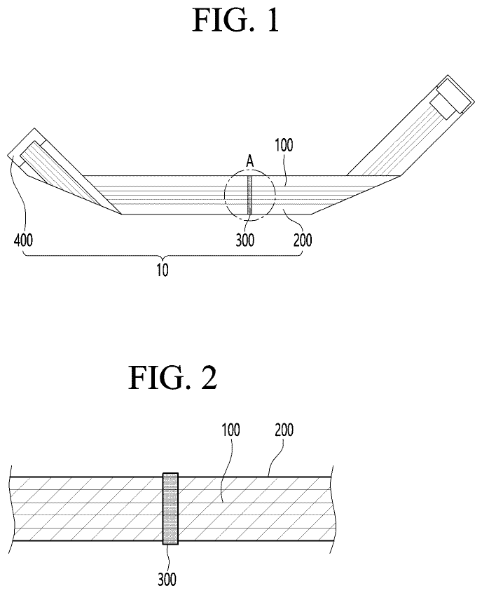

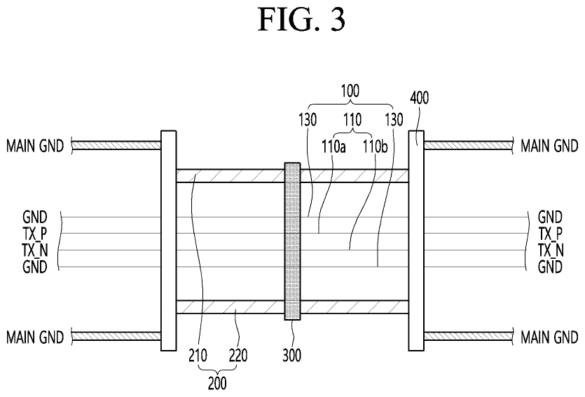

FIG. 1 is a view illustrating the overall configuration of a data transmission cable according to an embodiment of the present disclosure, and FIG. 2 is a view illustrating area A of FIG. 1 in detail.

As illustrated in FIGS. 1 and 2, the data transmission cable of the present disclosure may include a signal transfer line 100, an impedance matching sheet 200 covering the signal transfer line 100, and a conductive bending tape 300 wound around the impedance matching sheet 200.

In some cases, the present disclosure may further include connectors 400 disposed at both ends of the signal transfer line 100 to electrically connect the signal transfer line 100 to an external device.

Here, the connector 400 may be connected to the main ground line to ground at least one of the conductive bending tape 300 and the impedance matching sheet 200.

In addition, the signal transfer line 100 may include a plurality of data lines and a plurality of ground lines.

As an example, the ground line may be disposed at a regular interval above and below the data line.

Here, an air gap or an electrical insulator may be formed between the ground line and the data line to insulate them from each other.

As another example, the ground line may be disposed at regular intervals on the left and right sides of the data line, respectively.

Here, an air gap or an electrical insulator may be formed between the ground line and the data line to insulate them from each other.

Next, the data line may include at least one of a first pair of data lines including a positive transmission line and a negative transmission line, and a second pair of data lines including a positive reception line and a negative reception line.

Here, the first pair of data lines may be disposed by stacking positive transmission lines and negative transmission lines at regular intervals, and the second pair of data lines may be disposed by stacking positive reception lines and negative reception lines at regular intervals.

At this time, an air gap or an electrical insulator may be formed between the positive transmission line and the negative transmission line to insulate them from each other.

Additionally, an air gap or electrical insulator may be formed between the positive reception line and the negative reception line to insulate them from each other.

Next, the impedance matching sheet 200 may include a first impedance matching sheet disposed above the signal transfer line 100 and a second impedance matching sheet disposed below the signal transfer line 100.

Here, the first and second impedance matching sheets may be electrically connected to each other through the conductive bending tape 300.

As an example, the impedance matching sheet 200 may include at least one insulating layer, a metal layer formed on the insulating layer, and a protective layer formed on the metal layer.

At this time, the insulating layer may be composed of at least one selected from nylon, polyimide, polyvinylacetate, polyurethane, polyester, Teflon-based resin, polyethylene, and polypropylene.

In some cases, the insulating layer may include at least one of CaCO₃, TiO₂, SiO₂, and nitride powder.

Additionally, the insulating layer of the impedance matching sheet 200 may be disposed to face the signal transfer line 100.

Here, an adhesive layer may be formed between the insulating layer of the impedance matching sheet 200 and the signal transfer line 100.

As an example, the adhesive layer may include a thermosetting resin.

Additionally, the metal layer may be formed by being inserted into a groove formed in the insulating layer.

In some cases, the metal layer may be separated into a plurality of metal lines and respectively disposed in a plurality of grooves formed in the insulating layer.

As another case, the metal layer may be formed of metal lines in a lattice structure and disposed in grooves in the form of a lattice structure formed in the insulating layer.

Meanwhile, the conductive bending tape 300 may be disposed to be wound on the outer surface of the impedance matching sheet 200 in a direction perpendicular to the longitudinal direction of the impedance matching sheet 200.

Here, a disposition position and number of disposition of the conductive bending tape 300 may be determined based on the signal frequency of the data transmitted through the signal transfer line 100, the wavelength corresponding to the signal frequency, the noise antenna length of the impedance matching sheet 200 corresponding to the wavelength, and the total length of the impedance matching sheet 200.

As an example, the wavelength may be calculated through a formula consisting of λ=c/f (where λ is the wavelength, c is the speed of light 3×108, and f is the signal frequency of the data transmitted through the signal transfer line).

In addition, the noise antenna length of the impedance matching sheet 200 may be determined based on the specific wavelength of wavelengths including λ, λ/2, λ/4, λ/8, λ/16, λ/32, and λ/64, in which the impedance matching sheet 200 is operated as a noise antenna.

Here, a specific wavelength may be preset for each signal frequency band of data transmitted through the signal transfer line 100.

As an example, the specific wavelength may be extracted from a look-up table in which the specific wavelength at which the impedance matching sheet 200 is operated as a noise antenna for each signal frequency band is preset and stored.

In other words, the present disclosure may measure the signal frequency of data transmitted through the signal transfer line 100, calculate the wavelength corresponding to the measured signal frequency, select the noise antenna length of the impedance matching sheet 200 corresponding to the wavelength, obtain the total length of the impedance matching sheet 200, and when the total length of the impedance matching sheet 200 is the noise antenna length or more, the disposition position and the number of disposition of conductive bending tape 300 may be determined based on the total length of the impedance matching sheet 200.

Here, the disposition position of the conductive bending tape 300 may be determined as one point and the number of the disposition thereof may be determined as one so that one conductive bending tape 300 is disposed at ½ of the total length of the impedance matching sheet 200 when the total length of the impedance matching sheet 200 is the noise antenna length or more and less than twice the noise antenna length.

In addition, the disposition position of the conductive bending tape 300 may be determined as N+1 point and the number of the disposition thereof may be determined as N+1 so that one conductive bending tape 300 is disposed at every 1/N+2 of the total length of the impedance matching sheet 200 when the total length of the impedance matching sheet 200 is N+1 times the length of the noise antenna or more.

Additionally, the conductive bending tape 300 may be determined not to be disposed on the impedance matching sheet 200 when the total length of the impedance matching sheet 200 is less than the noise antenna length.

For example, when the conductive bending tape 300 has a signal frequency of data transmitted through the signal transfer line 100 of 99 MHz, has a wavelength corresponding to the signal frequency of 303.0 cm, and the noise antenna length of the impedance matching sheet 200 corresponding to the wavelength is a λ/16 wavelength, that is 18.9 cm, and the total length of the impedance matching sheet 200 is 30 cm, it may be determined that one conductive bending tape 300 is disposed at a point 15 cm from the end of ½ the total length of the impedance matching sheet 200.

As such, in the present disclosure, in order to suppress the impedance matching sheet 200 from forming a noise antenna and emitting EMI noise, the conductive bend tape 300 may be attached to an area less than the minimum length where noise antenna characteristics appear.

Also, when the length of the impedance matching sheet 200 is the minimum length or more, one conductive bending tape 300 or a plurality of conductive bending tapes 300 may be disposed according to the length of the impedance matching sheet 200.

Here, the number of conductive bending tapes 300 may increase as the length of the impedance matching sheet 200 increases.

In addition, the minimum length of the impedance matching sheet 200 is the noise antenna length at which the impedance matching sheet 200 is operated as a noise antenna, and the noise antenna length may be varied according to the wavelength corresponding to the signal frequency of the data transmitted through the signal transfer line 100.

At this time, the plurality of conductive bending tapes 300 may be disposed at regular intervals, and the gap between the conductive bending tapes 300 may be less than the noise antenna length at which the impedance matching sheet 200 operates as a noise antenna.

Additionally, the length of the conductive bending tape 300 may be longer than the sum of the upper and lower surface widths of the impedance matching sheet 200.

In other words, when the impedance matching sheet 200 includes a first impedance matching sheet disposed above the signal transmission line 100 and a second impedance matching sheet disposed below the signal transmission line 100, the minimum length of the conductive bending tape 300 may be the total length of the sum of the width length of the first impedance matching sheet, the width length of the second impedance matching sheet, and the length of the gap between the outer surface of the first impedance matching sheet and the outer surface of the second impedance matching sheet.

Next, at least one of the conductive bending tape 300 and the impedance matching sheet 200 may be grounded by directly contacting the ground part.

Next, the conductive bending tape 300 may be made of the same material as the impedance matching sheet 200 or may be made of a different material.

Also, the width of the conductive bending tape 300 may be narrower than the width of the impedance matching sheet 200.

As such, the present disclosure may reduce the generation of EMI noise due to data transmission by disposing the conductive bending tape to be wound on the outer surface of the impedance matching sheet.

In addition, the present disclosure has a structure of wrapping a conductive bending tape on the outer surface of the impedance matching sheet in a direction perpendicular to the longitudinal direction of the impedance matching sheet, so the manufacturing cost may be low, an automated process may be possible, and EMI noise emission may be suppressed.

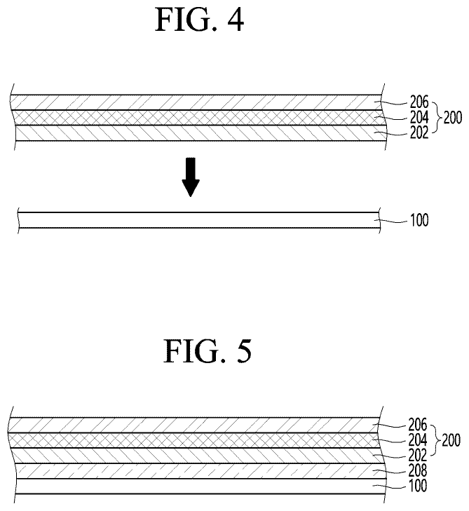

FIG. 3 is a view illustrating the inside of a side of a data transmission cable in detail according to an embodiment of the present disclosure.

As illustrated in FIG. 3, the signal transfer line 100 of the present disclosure may include a plurality of data lines 110 and a plurality of ground lines 130, and the ground line GND 130 may be disposed at regular intervals at the upper and lower portions of a data line 110.

Here, an air gap or an electrical insulator may be formed between the ground line GND 130 and the data line 110 to insulate them from each other.

In addition, the data line 110 may include at least one of a first pair of data lines including a positive transmission line Tx_P 110a and a negative transmission line Tx_N 110b and a second pair of data lines including a positive reception line (not illustrated) and a negative reception line (not illustrated).

Here, the first pair of data lines may be disposed so that a positive transmission line Tx_P 110a and a negative transmission line Tx_N 110b are stacked at regular intervals, and the second pair of data lines may be disposed so that a positive reception line (not illustrated) and negative reception lines (not illustrated) may be stacked at regular intervals.

At this time, an air gap or an electrical insulator may be formed between the positive transmission line Tx_P 110a and the negative transmission line Tx_N 110b to insulate them from each other.

Additionally, an air gap or electrical insulator may be formed between the positive reception line (not illustrated) and the negative reception line (not illustrated) to insulate them from each other.

Next, the impedance matching sheet 200 of the present disclosure may include a first impedance matching sheet 210 disposed above the signal transfer line 100, and a second impedance matching sheet 220 disposed below the signal transfer line 100.

Here, the first and second impedance matching sheets 210 and 220 may be electrically connected to each other through the conductive bending tape 300.

In this way, the impedance matching sheet 200 including the first and second impedance matching sheets 210 and 220 emits Electro Magnetic Interference (EMI) noise when the impedance matching sheet has a length that exhibits noise antenna characteristics, but the conductive bend tape 300 is attached to a specific location and electrically connects the first and second impedance matching sheets 210 and 220, thereby suppressing the formation of a noise antenna of the impedance matching sheet 200 and minimizing EMI noise from generating at a low manufacturing cost.

Next, the conductive bending tape 300 may be disposed to be wound on the outer surface of the impedance matching sheet 200 in a direction perpendicular to the longitudinal direction of the impedance matching sheet 200.

The disposition position and the number of the disposition of the conductive bending tape 300 may be determined based on the signal frequency of the data transmitted through the signal transfer line 100, the wavelength corresponding to the signal frequency, the noise antenna length of the impedance matching sheet 200 corresponding to the wavelength, and the total length of the impedance matching sheet 200.

In other words, the present disclosure may measure the signal frequency of data transmitted through the signal transfer line 100, calculate the wavelength corresponding to the measured signal frequency, select the noise antenna length of the impedance matching sheet 200 corresponding to the wavelength, obtain the total length of the impedance matching sheet 200, and when the total length of the impedance matching sheet 200 is the noise antenna length or more, the disposition position and the number of the disposition of the conductive bending tape 300 may be determined based on the total length of the impedance matching sheet 200.

Next, the connector 400 of the present disclosure can be disposed at both ends of the signal transfer line 100 to electrically connect the signal transfer line 100 to an external device.

Here, the connector 400 may be connected to the main ground line main GND to ground at least one of the conductive bending tape 300 and the impedance matching sheet 200.

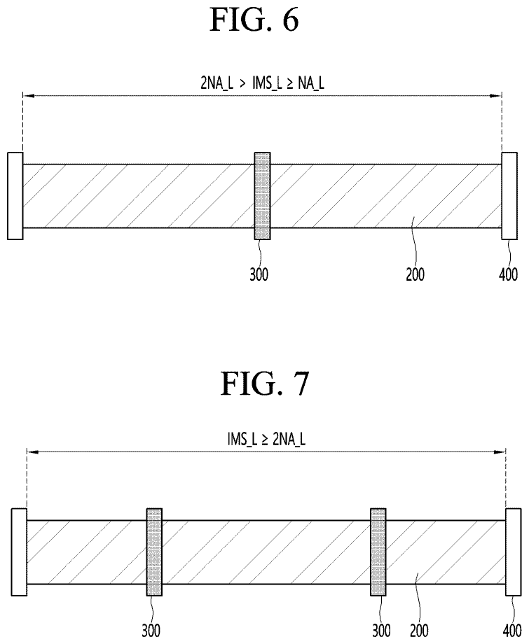

FIGS. 4 and 5 are views for explaining the structure of an impedance matching sheet according to an embodiment of the present disclosure.

FIG. 4 is a view illustrating the structure before the impedance matching sheet 200 is adhered to the signal transfer line 100, and FIG. 5 is a view illustrating the structure after the impedance matching sheet 200 is adhered to the signal transfer line 100.

As illustrated in FIGS. 4 and 5, the impedance matching sheet 200 may include at least one insulating layer 202, a metal layer 204 formed on the insulating layer 202, and a protective layer 206 formed on the metal layer 204.

At this time, the insulating layer 202 may be made of at least one selected from nylon, polyimide, polyvinylacetate, polyurethane, polyester, Teflon-based resin, polyethylene, and polypropylene.

In some cases, the insulating layer 202 may include at least one of CaCO₃, TiO₂, SiO₂, and nitride powder.

Additionally, the insulating layer 202 of the impedance matching sheet 200 may be disposed to face the signal transfer line 100.

As illustrated in FIG. 5, the insulating layer 202 of the impedance matching sheet 200 may be adhered to the signal transfer line 100.

Here, an adhesive layer 208 may be formed between the insulating layer 202 of the impedance matching sheet 200 and the signal transfer line 100.

As an example, the adhesive layer 208 may include a thermosetting resin.

As such, the present disclosure may implement a flexible flat cable (FFC) by attaching the impedance matching sheet 200 to the upper and lower portions of the signal transfer line 100, respectively.

Additionally, in the present disclosure, the insulating layer 202 of the impedance matching sheet 200 may be implemented as a plurality of layers according to the intended use of the data transmission cable.

In some cases, the metal layer 204 of the impedance matching sheet 200 may be formed by being inserted into a groove formed in the insulating layer 202.

In another case, when the metal layer 204 of the impedance matching sheet 200 is separated into a plurality of metal lines, a plurality of metal lines may be respectively disposed in a plurality of grooves formed in the insulating layer 202.

As another case, when the metal layer 204 of the impedance matching sheet 200 is formed of metal lines in a lattice structure, the metal line may be disposed in a groove of the lattice structure formed in the insulating layer 202.

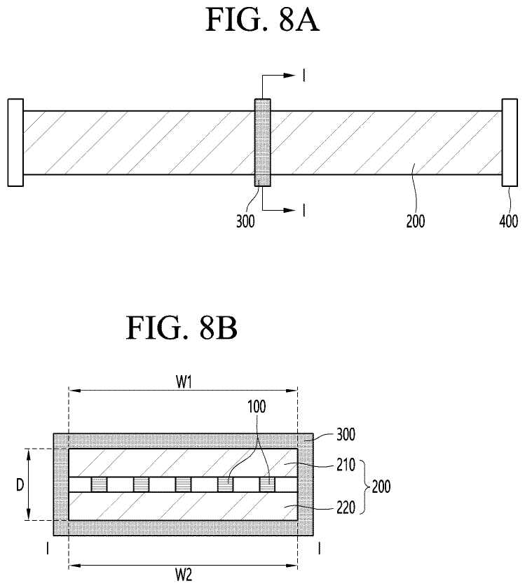

FIGS. 6 and 7 are views for explaining the disposition position and the disposition number of conductive bending tapes according to an embodiment of the present disclosure.

FIG. 6 is a view illustrating an embodiment in which only one conductive bending tape is disposed at a specific location, and FIG. 7 is a view illustrating an embodiment in which a plurality of conductive bending tapes are disposed at a plurality of specific locations.

As illustrated in FIGS. 6 and 7, one conductive bending tape 300 or a plurality of conductive bending tapes 300 of the present disclosure may be disposed according to the length IMS_L of the impedance matching sheet 200 when the length IMS_L of the impedance matching sheet 200 is the minimum length or more.

For example, the number of conductive bending tapes 300 may increase as the length IMS_L of the impedance matching sheet 200 increases.

In other words, the minimum length of the impedance matching sheet 200 may be the noise antenna length at which the impedance matching sheet 200 is operated as a noise antenna.

Here, the noise antenna length may vary according to the wavelength corresponding to the signal frequency of data transmitted through the signal transfer line.

In addition, the disposition position and the number of the disposition of the conductive bending tape 300 may be determined based on the signal frequency of the data transmitted through the signal transfer line, the wavelength corresponding to the signal frequency, the noise antenna length NA_L of the impedance matching sheet 200 corresponding to the wavelength, and the length IMS_L of the impedance matching sheet 200.

For example, the wavelength corresponding to the signal frequency may be calculated through the formula consisting of λ=c/f (where λ is the wavelength, c is the speed of light 3×108, and f is the signal frequency of the data transmitted through the signal transfer line).

In addition, the noise antenna length NA_L of the impedance matching sheet 200 may be determined based on the specific wavelength of wavelengths including λ, λ/2, λ/4, λ/8, λ/16, λ/32, and λ/64, in which the impedance matching sheet 200 is operated as a noise antenna.

Here, a specific wavelength may be preset for each signal frequency band of data transmitted through a signal transfer line.

As an example, the specific wavelength may be extracted from a look-up table in which the specific wavelength at which the impedance matching sheet 200 is operated as a noise antenna for each signal frequency band is preset and stored.

In other words, in the present disclosure, when the signal frequency of data transmitted through a signal transfer line is measured, the wavelength corresponding to the measured signal frequency is calculated, the noise antenna length NA_L of the impedance matching sheet 200 corresponding to the wavelength is selected, the length IMS_L of the impedance matching sheet 200 is obtained, and when the length IMS_L of the impedance matching sheet 200 is the noise antenna length NA_L or more, the disposition position and the number of the disposition of the conductive bending tape 300 may be determined based on the length IMS_L of the impedance matching sheet 200.

As illustrated in FIG. 6, the disposition position of the conductive bending tape 300 may be determined as one point and the number of the disposition thereof may be determined as one so that one conductive bending tape 300 is disposed at ½ of the length IMS_L of the impedance matching sheet 200 when the length IMS_L of the impedance matching sheet 200 is the noise antenna length NA_L or more and less than twice the noise antenna length 2NA_L.

For example, when the conductive bending tape 300 has a signal frequency of data transmitted through the signal transfer line 100 of 99 MHz, has a wavelength corresponding to the signal frequency of 303.0 cm, and the noise antenna length NA_L of the impedance matching sheet 200 corresponding to the wavelength is a λ/16 wavelength, that is 18.9 cm, and the length IMS_L of the impedance matching sheet 200 is 30 cm, it may be determined that one conductive bending tape 300 is disposed at a point 15 cm from the end of ½ the length IMS_L of the impedance matching sheet 200.

In addition, as illustrated in FIG. 7, the disposition position of the conductive bending tape 300 may be determined as N+1 point and the number of the disposition thereof may be determined as N+1 so that one conductive bending tape 300 is disposed at every 1/N+2 of the length IMS_L of the impedance matching sheet 200 when the length IMS_L of the impedance matching sheet 200 is N+1 times the length NA_L of the noise antenna or more.

At this time, the plurality of conductive bending tapes 300 may be disposed at regular intervals, and the gap between the conductive bending tapes 300 may be less than the noise antenna length NA_L at which the impedance matching sheet 200 is operated as a noise antenna.

Additionally, the conductive bending tape 300 may be determined not to be placed on the impedance matching sheet 200 when the length IMS_L of the impedance matching sheet 200 is less than the noise antenna length NA_L.

As such, in the present disclosure, in order to suppress the impedance matching sheet 200 from forming a noise antenna and emitting EMI noise, the conductive bend tape 300 may be attached to an area less than the minimum length where noise antenna characteristics appear.

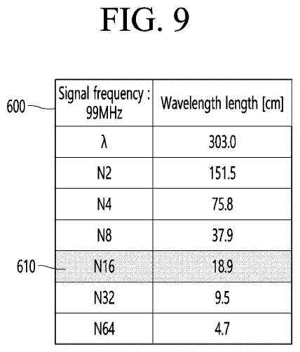

FIGS. 8A and 8B are views for explaining the length of a conductive bending tape according to an embodiment of the present disclosure.

FIG. 8A is a view illustrating a data transmission cable of the present disclosure, and FIG. 8B is a view illustrating a structural cross section along line I-I of the data transmission cable of FIG. 8A.

As illustrated in FIG. 8A, the data transmission cable of the present disclosure may include a conductive bending tape 300 disposed to be wound on the outer surface of the impedance matching sheet 200 in a direction perpendicular to the longitudinal direction of the impedance matching sheet 200 to which the connector 400 is connected.

As illustrated in FIG. 8B, the length of the conductive bending tape 300 may be longer than the sum of the length of the width of the upper surface and the length of the width of the lower surface of the impedance matching sheet 200.

In other words, when the impedance matching sheet 200 includes a first impedance matching sheet 210 disposed above the signal transmission line 100 and a second impedance matching sheet 220 disposed below the signal transmission line 100, the minimum length of the conductive bending tape 300 may be the total length of the sum of the width length W1 of the first impedance matching sheet 210, the width length W2 of the second impedance matching sheet 220, and the length D of the gap between the outer surface of the first impedance matching sheet 210 and the outer surface of the second impedance matching sheet 220.

As such, the present disclosure may reduce EMI noise emission at minimal cost by disposing the conductive bending tape 300 to be wound around the outer surface of the impedance matching sheet 200 with only the minimum length.

In addition, the present disclosure may reduce EMI noise emission at minimal cost by disposing the conductive bending tape 300 to be wound around the outer surface of the impedance matching sheet 200 with a minimum thickness.

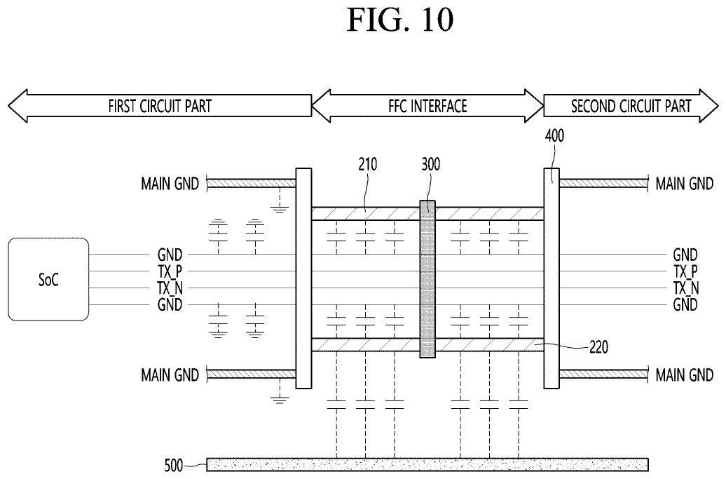

FIG. 9 is a diagram illustrating a lookup table in which a specific wavelength at which an impedance matching sheet operates as a noise antenna according to an embodiment of the present disclosure is preset.

The disposition position and the number of the disposition of the conductive bending tape 300 of the present disclosure may be determined based on the signal frequency of the data transmitted through the signal transfer line, the wavelength corresponding to the signal frequency, the noise antenna length of the impedance matching sheet corresponding to the wavelength, and the total length of the impedance matching sheet.

As an example, the wavelength may be calculated through a formula consisting of λ=c/f (where λ is the wavelength, c is the speed of light 3×108, and f is the signal frequency of the data transmitted through the signal transfer line).

In addition, the noise antenna length of the impedance matching sheet may be determined based on the specific wavelength of wavelengths including λ, λ/2, λ/4, λ/8, λ/16, λ/32, and λ/64, in which the impedance matching sheet is operated as a noise antenna.

Here, a specific wavelength may be preset for each signal frequency band of data transmitted through a signal transfer line.

As illustrated in FIG. 9, the specific wavelength 610 may be extracted from the lookup table 600 in which the specific wavelength at which the impedance matching sheet is operated as a noise antenna for each signal frequency band is preset and stored.

As an example, the lookup table 600 may store wavelength length values calculated for each wavelength corresponding to the signal frequency of 99 MHz when the signal frequency of data transmitted through the signal transfer line is 99 MHz, and the wavelength length value of the wavelength length values at which the impedance matching sheet forms the noise antenna may be preset and stored.

Here, in the lookup table 600, when the signal frequency of data transmitted through the signal transfer line is 99 MHz, wavelength length values corresponding to the wavelength λ, λ/2, λ/4, λ/8, λ/16, λ/32, λ/64 may be stored.

The wavelength length value may be calculated through the formula consisting of λ=c/f (where λ is the wavelength, c is the speed of light 3×108, and f is the signal frequency of the data transmitted through the signal transfer line).

In addition, in the look-up table 600, when the signal frequency of data transmitted through the signal transfer line is 99 MHz, and the wavelength length value of the wavelength length values at which the impedance matching sheet forms a noise antenna may be preset the wavelength length value of 18.9 cm at the wavelength λ/16 as the noise antenna length of the impedance matching sheet.

In other words, the data transmission cable whose data signal frequency corresponds to 99 MHz forms a noise antenna when the impedance matching sheet is 18.9 cm or more, so the wavelength length value of 18.9 cm at the wavelength λ/16 may be preset as the noise antenna length of the impedance matching sheet.

Therefore, in the present disclosure, the minimum length of the impedance matching sheet may be extracted from the lookup table 600 in which the specific wavelength 610 at which the impedance matching sheet is operated as a noise antenna is preset and stored for each signal frequency band.

As illustrated in FIG. 9, when the signal frequency of data transmitted through the signal transfer line is 99 MHz, the wavelength corresponding to the signal frequency is 303.0 cm, the noise antenna length of the impedance matching sheet corresponding to the wavelength is λ/16, that is, 18.9 cm. and the total length of the impedance matching sheet 200 is about 30 cm, the present disclosure may determine so that one conductive bending tape is disposed at a point about 15 cm from an end that is ½ of the total length of the impedance matching sheet 200.

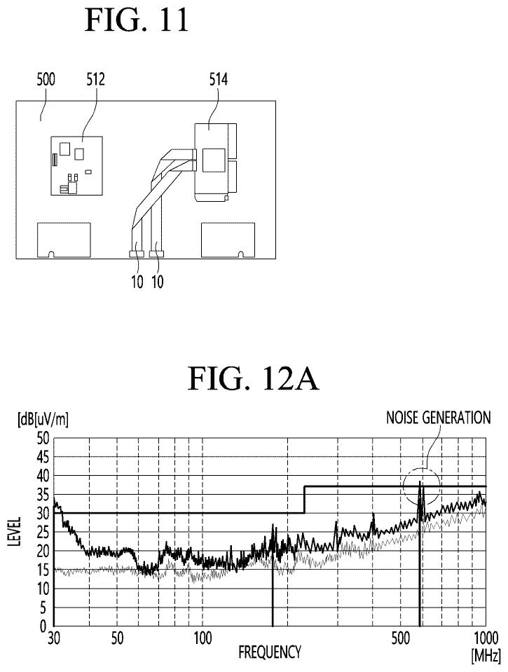

FIGS. 10 and 11 are views for explaining a display apparatus including a data transmission cable according to an embodiment of the present disclosure.

As illustrated in FIG. 10, the display apparatus of the present disclosure may include a display unit which displays an image, a driving control unit 510 which controls driving of the display unit, and a data transmission cable 10 which is connected between the first circuit part 512 and the second circuit part 514 of the driving control unit 510 to transmit data signals.

Here, the data transmission cable 10 may include an impedance matching sheet covering the signal transfer line, and a conductive bending tape disposed to be wound on the outer surface of the impedance matching sheet in a direction perpendicular to the longitudinal direction of the impedance matching sheet.

In addition, at least one of the conductive bending tape and the impedance matching sheet may be grounded by directly contacting the ground part.

As an example, the ground part may include a metal module cover 500 which supports the driving control unit 510.

As illustrated in FIG. 10, the signal transfer line 100 of the data transmission cable 10 may include a plurality of data lines and a plurality of ground lines.

Here, the data line may include at least one of a first pair of data lines including a positive transmission line Tx_P and a negative transmission line Tx_N, and a second pair of data lines including a positive reception line (not illustrated) and a negative reception line (not illustrated).

Additionally, the ground line GND may be disposed above and below the data line, respectively.

Next, the impedance matching sheet of the data transmission cable 10 may include a first impedance matching sheet 210 disposed above the signal transfer line and a second impedance matching sheet 220 disposed below the signal transfer line.

Here, the first and second impedance matching sheets 210 and 220 may be electrically connected to each other through the conductive bending tape 300.

In this way, the impedance matching sheet 200 including the first and second impedance matching sheets 210 and 220 emits Electro Magnetic Interference (EMI) noise when the impedance matching sheet has a length that exhibits noise antenna characteristics, but the conductive bend tape 300 is attached to a specific position and electrically connects the first and second impedance matching sheets 210 and 220, thereby suppressing the formation of a noise antenna of the impedance matching sheet 200 and minimizing EMI noise from generating at a low manufacturing cost.

Next, the conductive bending tape 300 may be disposed to be wound on the outer surface of the impedance matching sheet 200 in a direction perpendicular to the longitudinal direction of the impedance matching sheet 200.

The disposition position and the number of the disposition of the conductive bending tape 300 may be determined based on the signal frequency of the data transmitted through the signal transfer line, the wavelength corresponding to the signal frequency, the noise antenna length of the impedance matching sheet 200 corresponding to the wavelength, and the total length of the impedance matching sheet 200.

Next, the connector 400 of the present disclosure may be disposed at both ends of the signal transfer line to electrically connect the signal transfer line to the driving control unit.

Here, the connector 400 may be connected to the main ground line main GND to ground at least one of the conductive bending tape 300 and the impedance matching sheet 200.

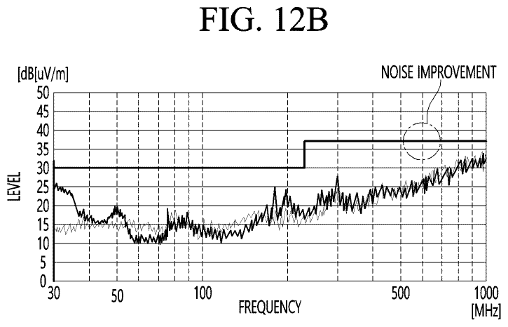

FIGS. 12A and 12B are graphs illustrating noise reduction in a data transmission cable according to an embodiment of the present disclosure.

FIG. 12A is a graph measuring the signal frequency of a data transmission cable without a conductive bending tape attached, and FIG. 12B is a graph measuring the signal frequency of a data transmission cable with a conductive bending tape of the present disclosure attached.

As illustrated in FIG. 12A, in the case of a data transmission cable without a conductive bending tape attached, when the signal frequency of data transmitted through the signal transfer line is measured, it can be seen that noise is generated in a frequency range of about 585.7 MHz.

In other words, a data transmission cable without a conductive bending tape attached may emit Electro Magnetic Interference (EMI) noise because the impedance matching sheet forms a noise antenna structure.

In contrast, in the case of a data transmission cable with a conductive bending tape attached, as illustrated in FIG. 12B, when measuring the signal frequency of data transmitted through the signal transfer line, it can be seen that noise emission is suppressed and noise is reduced even in the frequency range of about 585.7 MHz where noise generated.

In other words, a data transmission cable with a conductive bending tape attached may have a noise improvement effect that minimizes EMI noise generation by suppressing the formation of a noise antenna on the impedance matching sheet.

As such, the present disclosure may reduce the generation of EMI noise due to data transmission by disposing the conductive bending tape to be wound on the outer surface of the impedance matching sheet.

In addition, the present disclosure has a structure of wrapping a conductive bending tape on the outer surface of the impedance matching sheet in a direction perpendicular to the longitudinal direction of the impedance matching sheet, so the manufacturing cost may be low, an automated process may be possible, and EMI noise emission may be suppressed.

Above, embodiments of the present disclosure have been described with reference to the attached drawings, but those skilled in the art to which this disclosure belongs will understand that the present disclosure can be implemented in other specific forms without changing the technical idea or essential features thereof. Therefore, the embodiments described above should be understood in all respects as illustrative and not restrictive.

What is claimed is:

1. A data transmission cable comprising:
a signal transfer line;
an impedance matching sheet configured to cover the signal transfer line; and,
a conductive bending tape wound around the impedance matching sheet,
wherein the conductive bending tape is disposed to be wound on an outer surface of the impedance matching sheet in a direction perpendicular to a longitudinal direction of the impedance matching sheet.

2. The data transmission cable of claim 1,
wherein the impedance matching sheet includes:
a first impedance matching sheet disposed above the signal transfer line; and,
a second impedance matching sheet disposed below the signal transfer line.

3. The data transmission cable of claim 2,
wherein the first and second impedance matching sheets are electrically connected to each other through the conductive bending tape.

4. The data transmission cable of claim 1,
wherein a disposition position and number of disposition of the conductive bending tape are determined based on the signal frequency of the data transmitted through the signal transfer line, the wavelength corresponding to the signal frequency, the noise antenna length of the impedance matching sheet corresponding to the wavelength, and the total length of the impedance matching sheet.

5. The data transmission cable of claim 4,
wherein the wavelength is calculated through the formula consisting of λ=c/f (where λ is the wavelength, c is the speed of light 3×108, and f is the signal frequency of the data transmitted through the signal transfer line).

6. The data transmission cable of claim 4,
wherein the noise antenna length of the impedance matching sheet is determined based on a specific wavelength of the wavelengths including λ, λ/2, λ/4, λ/8, λ/16, λ/32, and λ/64, in which the impedance matching sheet is operated as a noise antenna.

7. The data transmission cable of claim 6,
wherein the specific wavelength is preset for each signal frequency band of data transmitted through the signal transfer line.

8. The data transmission cable of claim 1,
wherein one conductive bending tape or the plurality of conductive bending tapes is or are disposed according to the length of the impedance matching sheet when the length of the impedance matching sheet is the minimum length or more.

9. The data transmission cable of claim 8,
wherein the minimum length of the impedance matching sheet is the noise antenna length in which the impedance matching sheet is operated as a noise antenna, and
wherein the noise antenna length is varied according to the wavelength corresponding to the signal frequency of the data transmitted through the signal transfer line.

10. The data transmission cable of claim 8,
wherein the plurality of conductive bending tapes are disposed at regular intervals, and
wherein a gap between the conductive bending tapes is less than the length of the noise antenna operated as a noise antenna.

11. The data transmission cable of claim 1,
wherein the length of the conductive bending tape is longer than the sum of the length of the width of the upper surface and the length of the width of the lower surface of the impedance matching sheet.

12. The data transmission cable of claim 1,
wherein the minimum length of the conductive bending tape is the total length of all of them summed the length of the width of the first impedance matching sheet, the length of the width of the second impedance matching sheet, and the length of the gap between the outer surface of the first impedance matching sheet and the outer surface of the second impedance matching sheet when the impedance matching sheet includes a first impedance matching sheet disposed above the signal transfer line and a second impedance matching sheet disposed below the signal transfer line.

13. The data transmission cable of claim 1,
wherein at least one of the conductive bending tape and the impedance matching sheet is grounded by directly contacting a ground part.

14. The data transmission cable of claim 1, further comprising:
connectors placed at both ends of the signal transmission line and configured to electrically connecting the signal transfer line to an external device,
wherein the connector is connected to a main ground line to ground at least one of the conductive bending tape and the impedance matching sheet.

15. A display apparatus comprising:
a display unit configured to display an image;
a driving control unit configured to control driving of the display unit; and,
a data transmission cable connected between a first circuit part and a second circuit part of the driving control unit to transfer a data signal,
wherein the data transmission cable includes:
an impedance matching sheet configured to cover the signal transfer line, and
a conductive bending tape wound on an outer surface of the impedance matching sheet in a direction perpendicular to a longitudinal direction of the impedance matching sheet.
